(19) United States
(12) Patent Application Publication
(10) Pub. No.: US 2001/0034090 A1
(43) Pub. Date: Oct. 25, 2001

(54) METHODS FOR FORMING A GATE DIELECTRIC FILM OF A SEMICONDUCTOR DEVICE

(76) Inventor: MOON SIG JOO, ICHON-SHI (KR)

Correspondence Address: ERIC S. HYMAN, BLAKELY, SOKOLOFF, TAYLOR & ZAFMAN, 12400 WILSHIRE BOULEVARD, SEVENTH FLOOR, LOS ANGELES, CA, 90025

(21) Appl. No.: 09/345,297

(22) Filed: Jun. 30, 1999

(30) Foreign Application Priority Data
Jun. 30, 1998 (KR) 1998 25222

(51) Int. Cl. H01L 21/8234

(52) U.S. Cl. 438/197

(57) ABSTRACT

There is provided a method for forming a gate dielectric film of a semiconductor device, which can minimize the nitrogen induced defects inside the gate dielectric film to enhance the time dependent dielectric breakdown (TDDB) characteristic of the gate dielectric film. In the present invention, a silicon substrate is annealed with N₂O (or NO) gas under a low pressure of 10˜100 Torrs to form an oxynitride film on the silicon substrate, or a previously formed thermal oxide film is annealed with the same gas under the low pressure to be nitrified. The annealing under such a low pressure according to the invention allows the number of nitrogens existing inside the oxide film to be relatively fewer than the annealing under the normal pressure according to the method of the prior art, and does the nitrogens to be mainly piled-up at the boundary surface of Si/SiO₂. Accordingly, the present invention can allow the nitrogens to bind to the silicon dangling bonds, the strained Si—O bonds and the likes at the Si/SiO₂ boundary surface, and suppress the nitrogen induced defects such as bridging nitrogen centers derived from the excess nitrogens inside the oxide film.

### FIELD OF THE INVENTION

The present invention relates to a technology about a semiconductor device; and, more particularly, to a method for forming a gate dielectric film of a semiconductor device.

### DESCRIPTION OF THE PRIOR ART

A gate dielectric film may largely affect to the reliability and operation characteristics of a semiconductor device; thus, the process for forming the gate dielectric film is performed with hardness. Conventionally, the gate oxide film has been mainly formed by wet or dry oxidation process. Such a thermal oxide film is not sufficiently good in gate oxide integrity (GOI) because it is difficult to make the thermal oxide film thin. Therefore, a nitrified oxide film, that is, an oxynitride (SiOₓN_{y}) film has become to be used as a gate dielectric film.

Among the methods for forming an oxynitride film as a gate dielectric film, there have been studies on the method for forming the oxynitride film using N₂O gas. There has been mainly used the method for forming the oxynitride film using N₂O gas that a gate oxynitride film grows under normal pressure of N₂O gas at a high temperature of more than 900° C., or the previously formed thermal oxide film is annealed under normal pressure of N₂O gas to convert to the oxynitride film.

There are advantages in the prior art that it increases the hot carrier reliability and the diffusion barrier characteristic against boron penetration.

However, there are disadvantages particularly in the prior art that it deteriorates the time dependent dielectric breakdown (TDDB) of the gate dielectric film for gate side injection and decreases the yield of the gate dielectric film at the time that the deterioration is severe. It is considered that these come from nitrogen induced defects. Although the nitrogens may be bound with the silicon dangling bonds and the likes at the boundary surface of Si/SiO₂, the excess nitrogens inside the silicon oxide film may result in nitrogen induced defects such as bridging nitrogen centers.

### SUMMARY OF THE INVENTION

It is, therefore, an object of the present invention to provide a method for forming a gate dielectric film of a semiconductor device, which can enhance the time dependent dielectric breakdown (TDDB) characteristic of the gate dielectric film by minimizing the defects induced from nitrogens.

In accordance with an embodiment of the present invention, there is provided a method for forming a gate dielectric film of a semiconductor device, which comprises the steps of: forming a thermal oxide film on a silicon substrate; and annealing the thermal oxide film with nitrification gas under a pressure of 10 Torrs to 100 Torrs to perform nitrification of the thermal oxide film.

In accordance with another embodiment of the present invention, there is provided a method for forming a gate dielectric film of a semiconductor device, which comprises the step of annealing a silicon substrate with nitrification gas under a pressure of 10 Torrs to 100 Torrs to form a nitrified thermal oxide film (that is, an oxynitride film) on the silicon substrate.

The present invention is to anneal a silicon substrate under a low pressure of 10 Torrs to 100 Torrs, using N₂O (or NO) gas to form a gate oxynitride film, or to anneal a previously formed oxide film on a silicon substrate to perform the nitrification of the oxide film. The annealing under such a low pressure according to the invention allows the number of nitrogens existing inside the oxide film to be relatively fewer than the annealing under the normal pressure according to the method of the prior art, and does the nitogens to be mainly piled-up at the boundary surface of Si/SiO₂. Therefore, in the invention, the nitrogens are effectively bound with silicon dangling bonds, strained Si—O bonds and the likes, and the nitrogen induced defects such as bridging nitrogen centers resulted from the excess nitrogens inside the oxide film can be suppressed. The present invention can be applied to manufacturing the gate dielectric film of higher integrated memory device than 1 giga DRAM grade, the tunnel oxide film of flash electrically erasable programmable read only memory (EEPROM) and the like.

### BRIEF DESCRIPTION OF THE DRAWINGS

The above and other objects and features of the present invention will become apparent from the following description of preferred embodiments given in conjunction with the accompanying drawings, in which:

FIG. 1 is a graph showing the concentration of nitrogen contained in the thermal oxide film with the sputtering time (which represents the depth from the exposed surface of the thermal oxide film) for different annealing pressures;

FIG. 2 is a sectional view showing the processes for forming the gate oxynitride film according to an embodiment of the present invention;

FIG. 3 is a diagram showing the detailed processes for forming the gate oxynitride film according to an embodiment of the present invention;

FIG. 4 is a graph showing the time dependent dielectric breakdown (TDDB) characteristic of the gate dielectric films formed from the same thermal oxide film under different annealing pressures.

### DETAILED DESCRIPTION OF THE PREFERRED EMBODIMENTS

The invention will be illustrated in detail by the following preferred embodiment with reference to the accompanying drawings.

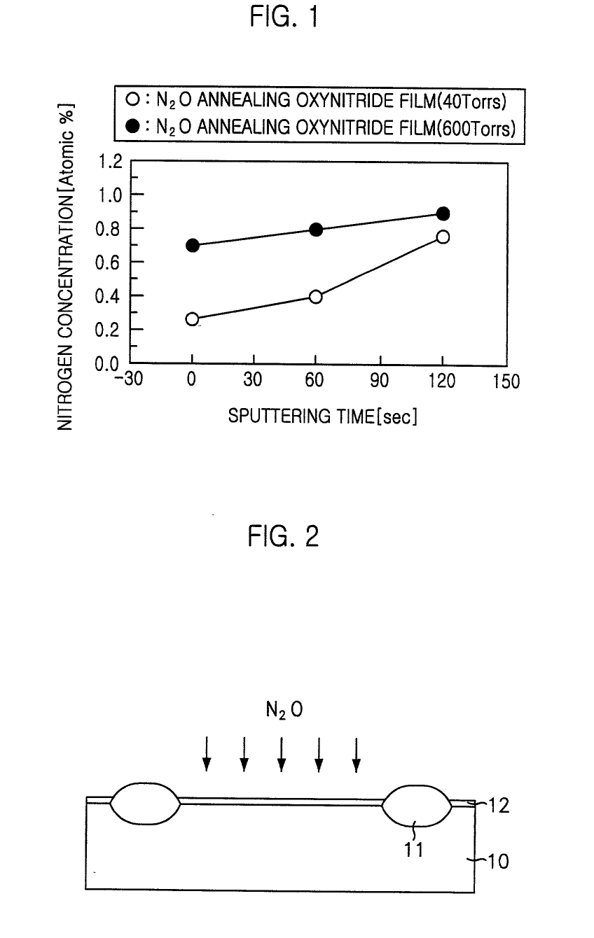

FIG. 1 is a graph showing the concentration of nitrogen contained in the thermal oxide film with the sputtering time (which represents the depth from the exposed surface of the thermal oxide film) for different annealing pressures. The concentration of nitrogen is measured by X-ray photoelectron spectroscopy (XPS). Wherein the sputtering time of 120 seconds corresponds to the depth from the exposed surface of the thermal oxide film to Si/SiO₂ boundary surface. That is, when the sputtering time is 120 seconds, the sputtered nitrogens are distributed at the Si/SiO₂ boundary surface.

As shown in the drawing, when N₂O annealing is performed under the pressure of 600 Torrs close to normal pressure, the nitrogens are not only piled up at the Si/SiO₂ boundary surface but also largely bound inside the thermal oxide film. It is the same as the above even if NO gas is used as a nitrification gas.

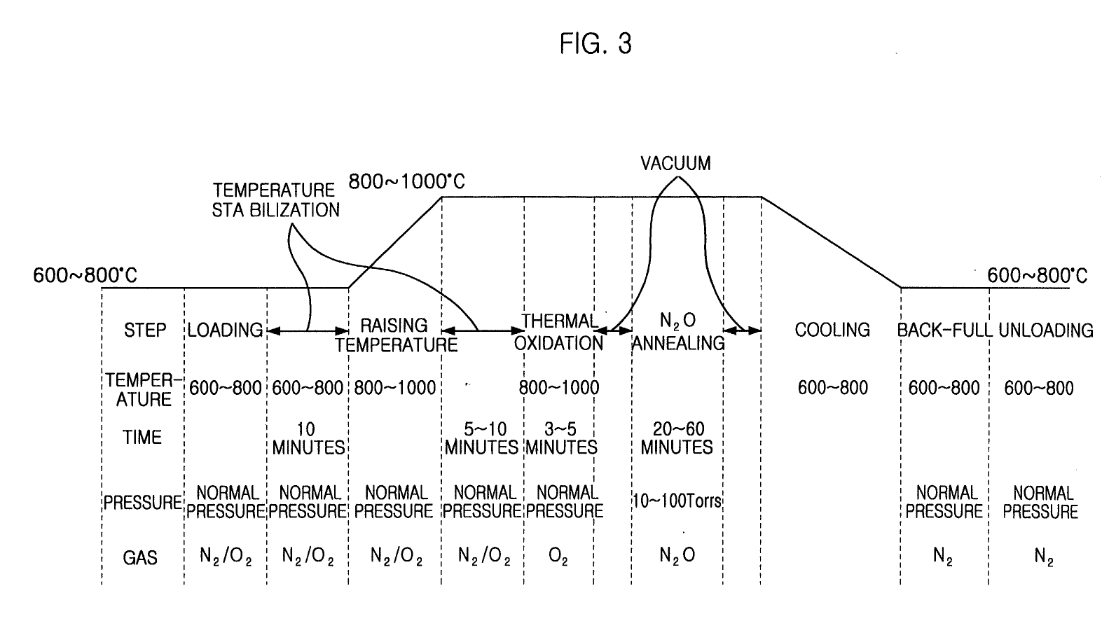

FIG. 2 is a sectional view showing the processes for forming the gate oxynitride film according to an embodiment of the present invention.

Referring to FIG. 2, field oxides 11 are grown on a silicon substrate 10 to define active regions. After a thermal oxide film 12 is formed on the active regions, an oxynitride film is formed by annealing the thermal oxide film with N₂O gas atmosphere under a pressure of 10˜100 Torrs.

FIG. 3 is a diagram showing the detailed processes for forming the gate oxynitride film according to an embodiment of the present invention.

As shown in the drawing, first, a wafer is loaded at a temperature of about 600˜800° C. into a batch type furnace capable of performing pressure-reducing process. After a temperature stabilization step, the wafer is heated to a temperature of 800˜1000° C. Subsequently, after another temperature stabilization step again, a thermal oxide film is grown some extent by oxidation of the silicon substrate for 3˜5 minutes under O₂ atmosphere. A pressure-reducing process is then performed very fast to change the inside of the furnace to vacuum state and thus to stop the oxidation. N₂O gas is then introduced into the furnace. Here, the pressure is adjusted to become 10˜100 Torrs, and the annealing time is within 1 hour (particularly, in a range of 20 minutes to 60 minutes) so as not largely to induce thermal budget. Subsequently, N₂O gas purge is performed to allow the inside of the furnace to become vacuum state. After the furnace is then cooled into a temperature of 600˜800° C., a N₂ back-filling step and a wafer unloading step are, in turn, performed. In the processes, the thickness of the entire oxide film can be adjusted, particularly, within 100 Å by mainly adjusting the thickness of the thermal oxide film at the thermal oxidation process before the N₂O annealing.

Referring to FIG. 1 again, when the N₂O annealing under the pressure of 40 Torrs is compared with the N₂O annealing under the pressure of 600 Torrs as the prior art, it allows the number of the nitrogens binding at the Si/SiO₂ boundary surface to be relatively more increased than the number of the nitrogens binding inside the thermal oxide film.

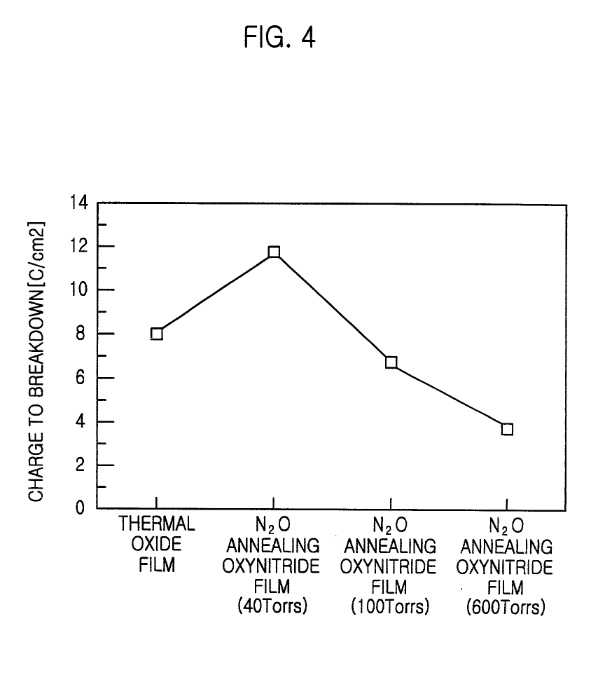

FIG. 4 is a graph showing the time dependent dielectric breakdown (TDDB) characteristic of the gate dielectric films formed from the same thermal oxide film under different annealing pressures. Here, the TDDB characteristic is measured by charge-to-breakdown at the time that breakdown occurs after constant current is input into the gate dielectric film.

As shown in the drawing, under the pressures of more than 100 Torrs, the TDDB characteristic starts to be more deteriorated than the thermal oxide film of the prior art (which is formed without N₂O annealing), and particularly, it is very largely deteriorated at the pressure of 600 Torrs close to the normal pressure. While it is largely enhanced at the pressure of 40 Torrs. The enhancement of the electric characteristic of the gate dielectric film results from suppression of defects generated from the nitrogens inside the oxide film as well as from effective binding of the nitrogens to silicon dangling bonds, strained Si—O bonds and the likes at the Si/SiO₂ boundary surface. When the annealing is performed under the pressure of less than 10 Torrs, the nitrification does not occur so much as for the nitrogens to bind to the silicon dangling bonds, the strained Si—O bonds and the likes, and the characteristic of the gate dielectric film cannot be enhanced. Therefore, the N₂O annealing should be performed under, at least, a pressure of more than 10 Torrs.

In another embodiment of the present invention, the oxynitride film can be formed from the silicon substrate by only low-pressure N₂O annealing without separate thermal oxidation process.

In still another embodiment of the present invention, NO gas can be used as a nitrification gas instead of N₂O gas used in the embodiments of the present invention as described above.

Although a batch type furnace capable of performing pressure-reducing process is used in the embodiments of the present invention, a rapid thermal process chamber or a single wafer type CVD chamber may be used to perform the pressure-reducing processes of the present invention.

While the present invention has been described with respect to certain preferred embodiments only, other modifications and variations may be made without departing from the spirit and scope of the present invention as set forth in the following claims.

What is claimed is:

1. A method for forming a gate dielectric film of a semiconductor device, which comprises the steps of:
forming a thermal oxide film on a silicon substrate; and
annealing the thermal oxide film with a nitrification gas under a pressure of 10 Torrs to 100 Torrs to perform nitrification of the thermal oxide film and thus, to form an oxynitride film on the substrate.

2. The method for forming a gate dielectric film of a semiconductor device according to claim 1, wherein the nitrification gas is N₂O gas or NO gas.

3. The method for forming a gate dielectric film of a semiconductor device according to claim 1, wherein the annealing is performed at a temperature of 800° C. to 1000° C.

4. The method for forming a gate dielectric film of a semiconductor device according to claim 2, wherein the annealing is performed at a temperature of 800° C. to 1000° C.

5. The method for forming a gate dielectric film of a semiconductor device according to claim 1, wherein the annealing is performed for 20 minutes to 60 minutes.

6. The method for forming a gate dielectric film of a semiconductor device according to claim 2, wherein the annealing is performed for 20 minutes to 60 minutes.

7. The method for forming a gate dielectric film of a semiconductor device according to claim 3, wherein the step for forming the thermal oxide film is performed at a temperature of 800° C. to 1000° C.

8. The method for forming a gate dielectric film of a semiconductor device according to claim 4, wherein the step for forming the thermal oxide film is performed at a temperature of 800° C. to 1000° C.

9. The method for forming a gate dielectric film of a semiconductor device according to claim 1, wherein the steps for forming the thermal oxide film and for annealing the oxide film are performed with an equipment selected from a group consisting of a batch type furnace capable of performing pressure-reducing process, a rapid thermal treatment chamber and a single wafer type chemical vapor deposition chamber.

10. The method for forming a gate dielectric film of a semiconductor device according to claim 2, wherein the steps for forming the thermal oxide film and for annealing the oxide film are performed with an equipment selected from a group consisting of a batch type furnace capable of performing pressure-reducing process, a rapid thermal treatment chamber and a single wafer type chemical vapor deposition chamber.

11. A method for forming a gate dielectric film of a semiconductor device, which comprises the step of annealing a silicon substrate with a nitrification gas under a pressure of 10 Torrs to 100 Torrs to form a nitrified thermal oxide film (that is, an oxynitride film) on the silicon substrate.

12. The method for forming a gate dielectric film of a semiconductor device according to claim 11, wherein the nitrification gas is N₂O gas or NO gas.

13. The method for forming a gate dielectric film of a semiconductor device according to claim 11, wherein the annealing is performed at a temperature of 800° C. to 1000° C.

14. The method for forming a gate dielectric film of a semiconductor device according to claim 12, wherein the annealing is performed at a temperature of 800° C. to 1000° C.

15. The method for forming a gate dielectric film of a semiconductor device according to claim 11, wherein the annealing is performed for 20 minutes to 60 minutes.

16. The method for forming a gate dielectric film of a semiconductor device according to claim 12, wherein the annealing is performed for 20 minutes to 60 minutes.

17. The method for forming a gate dielectric film of a semiconductor device according to claim 11, wherein the annealing is performed with an equipment selected from a group consisting of a batch type furnace capable of performing pressure-reducing process, a rapid thermal treatment chamber and a single wafer type chemical vapor deposition chamber.

18. The method for forming a gate dielectric film of a semiconductor device according to claim 12, wherein the annealing is performed with an equipment selected from a group consisting of a batch type furnace capable of performing pressure-reducing process, a rapid thermal treatment chamber and a single wafer type chemical vapor deposition chamber.
